(19) United States
(12) Patent Application Publication
(10) Pub. No.: US 2026/0101804 A1
(43) Pub. Date: Apr. 9, 2026

(54) LOW COST WAFER LEVEL PACKAGES AND SILICON

(71) Applicant: STMICROELECTRONICS PTE LTD, Singapore (SG)

(72) Inventor: Jing-En LUAN, Singapore (SG)

(73) Assignee: STMICROELECTRONICS PTE LTD, Singapore (SG)

(21) Appl. No.: 19/384,332

(22) Filed: Nov. 10, 2025

Related U.S. Application Data
(62) Division of application No. 17/860,491, filed on Jul. 8, 2022, now Pat. No. 12,494,447.
(60) Provisional application No. 63/203,539, filed on Jul. 27, 2021.

(51) Int. Cl. H01L 23/00; H01L 21/56; H01L 25/065; H01L 25/16

(52) U.S. Cl. CPC H10W 74/01; H10W 90/00; H10W 70/09; H10W 70/60; H10W 70/6523; H10W 72/0198; H10W 72/072; H10W 72/073; H10W 72/244; H10W 72/874; H10W 72/922; H10W 72/9415; H10W 72/944; H10W 74/15; H10W 90/20; H10W 90/22; H10W 90/722; H10W 90/732; H10W 99/00

(57) ABSTRACT

A wafer-level package includes a first integrated circuit die having pads on its front side and a second integrated circuit die having pads on its front side, with a back side of the second die attached to the front side of the first die by an adhesive layer. A resin layer containing an activatable catalyst material is disposed across the front side of the first die, along edge sides of the second die, and across the front side of the second die. Selected portions of the resin layer are activated by laser radiation and metallized to form a redistribution layer providing electrical interconnection between the dies. A solder resist layer is formed over the resin layer, and solder balls are connected to metallized portions of the redistribution layer. The laser-direct-structuring process enables formation of conductive interconnects extending over die edges without conventional drilling or photo-patterning.

### RELATED APPLICATION

This application is a divisional of U.S. patent application Ser. No. 17/860,491, filed Jul. 8, 2022, which claims priority to U.S. Provisional Application Patent No. 63/203,539, filed Jul. 27, 2021, the contents of both of which are incorporated by reference in their entireties.

### TECHNICAL FIELD

This disclosure is related to techniques for forming wafer-level packages and, in particular, to forming wafer-level packages having redistribution layers formed using laser direct structuring so as to enable the formation of compact packages containing multiple interconnected integrated circuit die.

### BACKGROUND

An integrated circuit die is packaged to protect the die from operating environments and to provide an electrical interface between a die and an electronic device in which the die is utilized. Traditionally, die packaging techniques were distinct from semiconductor manufacturing techniques used in wafer level processing. Recently, however, wafer level processing techniques, such as wafer level chip scale packaging (WLCSP) have begun to be used in constructing the die packages.

FIG. 1 is a cross-sectional view of a known package 10 that includes a first integrated circuit die 9 connected with a second integrated circuit die 8 through respective redistribution layers formed on the first integrated circuit die 9.

In greater detail, the first integrated circuit die 9 has a back side illustrated as being exposed, and a front side having pads 12a and 12b formed thereon, the pads 12a and 12b providing connection to internal circuits within the first integrated circuit die 9. A passivation layer 13 is disposed on the front side of the first integrated circuit die 9, and a solder resist layer 15 is formed on the passivation layer 13. A first redistribution layer formed within the passivation layer 13 and solder resist layer 15 includes interconnections 14a and 14d respectively connected to pads 12a and 12b, and interconnections 14b, 14c, 27a, and 27b connected to non-illustrated pads on the front side of the first integrated circuit die 9. Solder balls 16a-16d are respectively connected to interconnections 14a-14d.

The second integrated circuit die 8 has a back side illustrated as being encapsulated by encapsulation layer 23, and a front side having pads 19a and 19b formed thereon, the pads 19a and 19b providing connection to internal circuits within the second integrated circuit die 8. A passivation layer 20 is disposed on the front side of the second integrated circuit die 8, and a solder resist layer 22 is formed on the passivation layer 20. A second redistribution layer formed within the passivation layer 20 and the solder resist layer 22 includes interconnections 21a and 21b respectively connected to pads 19a and 19b. Solder balls 17a and 17b connect the interconnections 27a and 27b of the first integrated circuit die 9 to the interconnections 21a and 21b of the second integrated circuit die 8. Encapsulation layer 23 encapsulates the edge sides and front face of the second integrated circuit die 8 and seals it against the solder resist 15 of the first integrated circuit die 9.

Wafer level packages formed according to the wafer level processing techniques of the prior art such as in FIG. 1 have several limitations. For example, the cost of forming high density, large size, and high pin-count wafer-level packages may be higher than desirable, particularly when a fan-out arrangement is to be used. Moreover, wafer-level packages utilizing multiple integrated circuit die can be difficult to form, and the use of solder balls to connect the different die can consume an undesirable amount of space.

As such, further development is needed.

### SUMMARY

A wafer-level package is described that includes a first integrated circuit die having multiple pads on its front side and a second integrated circuit die having multiple pads on its front side. An adhesive layer attaches the back side of the second integrated circuit die to the front side of the first integrated circuit die. A resin layer surrounds the edge sides and front side of the second integrated circuit die and the front side of the first integrated circuit die. The resin layer includes an activatable catalyst material. A solder resist layer has its back surface in contact with the front surface of the resin layer. A redistribution layer includes first activated and metallized portions of the resin layer adjacent to the plurality of pads on the front side of the second integrated circuit die, second activated and metallized portions of the resin layer adjacent to the plurality of pads on the front side of the first integrated circuit die, and third activated and metallized portions of the resin layer extending from certain of the first activated and metallized portions down the edge sides of the second integrated circuit die and across the resin layer on the front side of the first integrated circuit die to form electrical connections between pads on the front side of the second integrated circuit die and locations on the resin layer on the front side of the first integrated circuit die.

Optionally, the wafer-level package may include fourth activated and metallized portions of the resin layer that electrically connect selected first activated and metallized portions to selected second activated and metallized portions, thereby electrically connecting selected pads on the front side of the second integrated circuit die to selected pads on the front side of the first integrated circuit die.

Optionally, the wafer-level package may include a fourth activated and metallized portion of the resin layer on the front side of the first integrated circuit die, a fifth activated and metallized portion electrically connecting one of the first activated and metallized portions to the fourth activated and metallized portion, and a passive component electrically connected to the fourth activated and metallized portion of the resin layer.

Optionally, a molding layer may encapsulate the passive component.

Optionally, a molding layer may encapsulate a portion of the first integrated circuit die and one of the second activated and metallized portions of the resin layer, with a pad formed on the molding layer and a via extending from the pad through the molding layer to contact one of the second activated and metallized portions of the resin layer, thereby electrically connecting the pad to that portion.

Optionally, the wafer-level package may include a chip connected to one of the third activated and metallized portions of the resin layer on the front side of the first integrated circuit die.

Optionally, a molding layer may encapsulate the chip.

Optionally, the molding layer encapsulating the chip may extend along one side of the second integrated circuit die and across a portion of the front side of the first integrated circuit die.

Optionally, the activatable catalyst material may include at least one of copper-chromium oxide spinel, copper sulfate, copper hydroxide phosphate, or cupric rhodanate.

Optionally, the solder resist layer may extend across the resin layer on the front sides of both the first and second integrated circuit dies.

Optionally, a coating may be applied to the back side of the first integrated circuit die.

Optionally, a second solder resist layer may be disposed on the back side of the first integrated circuit die with pads formed thereon.

Optionally, connectors may extend through the first integrated circuit die to provide electrical interconnection between the second solder resist layer and the resin layer.

A wafer-level package is also described that includes a first integrated circuit die having multiple pads on its front side and a second integrated circuit die having multiple pads on its front side. The back side of the second integrated circuit die faces and is attached to the front side of the first integrated circuit die by an adhesive layer. A resin layer is disposed on and across the front side of the first integrated circuit die, along edge sides of the second integrated circuit die, and across the front side of the second integrated circuit die, with the resin layer containing an activatable catalyst material. A redistribution layer is formed by activated and metallized portions of the resin layer, including interconnections extending from pads on the front side of the second integrated circuit die along the edge sides of the second integrated circuit die and across the resin layer on the front side of the first integrated circuit die to electrically connect the first and second integrated circuit dies.

Optionally, the activated and metallized portions of the resin layer may be defined by selective laser activation of the catalyst material within the resin layer.

Optionally, the metallized portions of the resin layer may be formed by plating on the activated portions of the resin layer.

Optionally, a solder resist layer may be disposed over the resin layer and cover the redistribution layer.

Optionally, the resin layer may include a laser direct structuring compatible material having embedded catalyst particles that become activatable when exposed to laser radiation.

Optionally, the redistribution layer may provide electrical connection between at least one pad on the front side of the second integrated circuit die and at least one pad on the front side of the first integrated circuit die.

Optionally, solder balls may be connected to metallized portions of the resin layer on the front side of the first integrated circuit die.

### BRIEF DESCRIPTION OF THE DRAWINGS

FIG. 1 is a cross-sectional view of a wafer-level package formed using prior art techniques.

FIGS. 2A-2B are cross sectional views of a first wafer-level package formed using techniques described herein.

FIGS. 3-11 illustrate the series of steps involved in fabricating the first wafer-level package of FIG. 2A.

FIG. 12 is a cross-sectional view of a second wafer-level package formed using techniques described herein.

FIGS. 13-19 illustrate the series of steps involved in fabricating the second wafer-level package of FIG. 12.

FIG. 20 is a cross-sectional view of a third wafer-level package formed using techniques described herein.

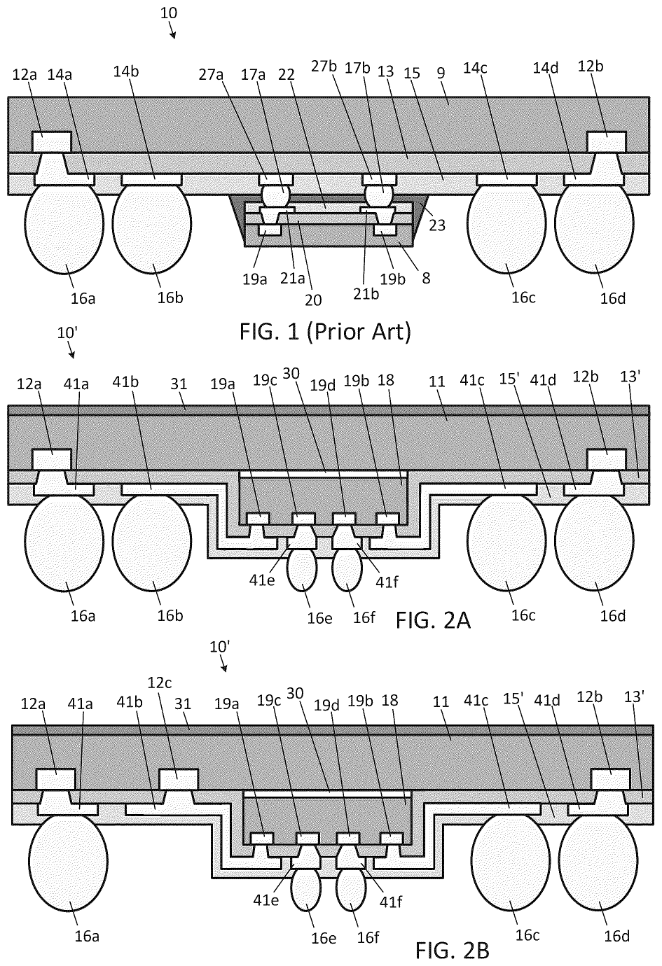

### DETAILED DESCRIPTION

The following disclosure enables a person skilled in the art to make and use the subject matter disclosed herein. The general principles described herein may be applied to embodiments and applications other than those detailed above without departing from the spirit and scope of this disclosure. This disclosure is not intended to be limited to the embodiments shown, but is to be accorded the widest scope consistent with the principles and features disclosed or suggested herein.

In the following disclosure, references to elements being “connected” may indicate that those components are electrically connected, and may be directly electrically connected, as well as being physically connected.

With initial reference to FIG. 2A, a first wafer level package 10′ is now described. The first wafer level package 10′ is comprised of a first integrated circuit die 11 having pads 12a and 12b on its front side and a coating 31 on its back side, and a second integrated circuit die 18 having pads 19a-19b on its front side and having its back side facing the front side of the first integrated circuit die 11. An adhesive layer 30 attaches the back side of the second integrated circuit die 18 to the front side of the first integrated circuit die 11. Therefore, notice that the pads 12a and 12b of the first integrated circuit die 11 do not face the pads 19a-19b of the second integrated circuit die 18.

A resin layer 13′ is disposed on and across the front side of the front integrated circuit die 11, on and up the edge sides of the second integrated circuit die 18, and on and across the front side of the second integrated circuit die 18. A solder resist layer 15′ is disposed on and across the resin layer 13′.

A redistribution layer (RDL) is formed within and on the resin layer 13′ and covered by the solder resist layer 15′. The RDL includes interconnections 41a and 41d respectively connected to the pads 12a and 12b and interconnections 41e and 41f respectively connected to the pads 19c and 19d. The RDL also includes interconnections 41b and 41c extending from the pads 19a and 19b, across the portion of the resin layer 13′ on the front of the second die 18, down the portions of the resin layer 13′ on the edge sides of the second die 18, and across the portions of the resin layer 13′ on the front of the integrated circuit die 11. In some instances, interconnections 41b or 41c may connect pads 19a or 19c to respective pads on the first integrated circuit die 11, for example shown in FIG. 2B where interconnection 41b connects pad 19a to a pad 12c on the first integrated circuit die 11.

Solder balls 16a and 16d are respectively connected to the interconnections 41a and 41d. Solder balls 16b and 16c are respectively connected to the portions of the interconnections 41b and 41c extending across the resin layer 13′ on the front of the first integrated circuit die 11. Solder balls 16e and 16f are respectively connected to the interconnections 41e and 41f.

Of note here is that the interconnections 41a-41f are not formed by conventional techniques. As will be explained below in detail, the interconnections 41a-41f are formed by activating desired areas of the resin layer 13′ (and drilling appropriate areas prior to activation of the desired areas and the walls of the holes formed via drilling), which contains an activatable catalyst, and then plating the activated areas.

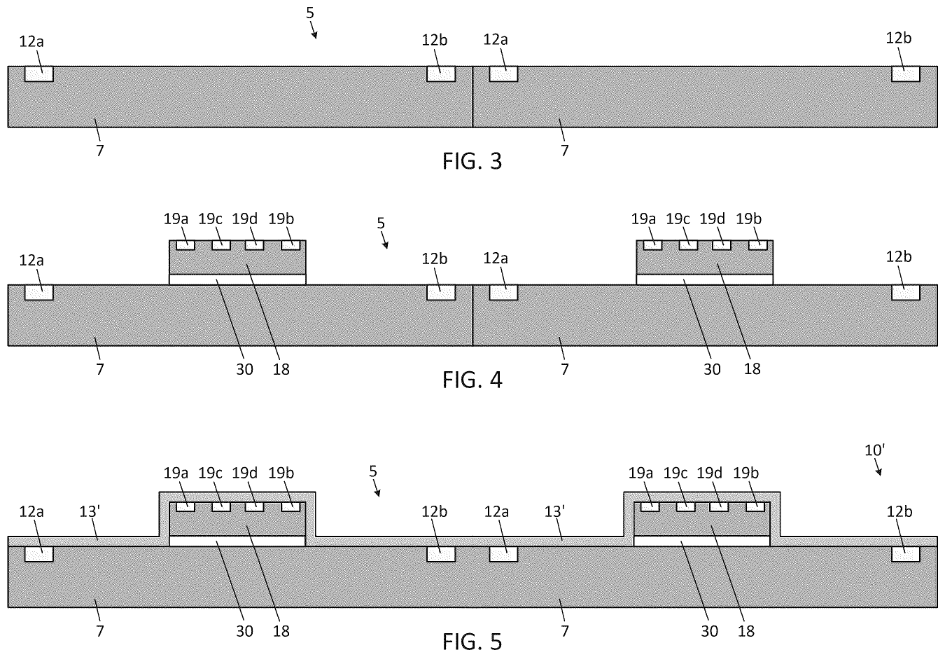

Formation of the first wafer level package 10′ is now described with reference to the series of drawing FIGS. 3-11. Referring first to FIG. 3, a single incoming wafer 5 has integrated circuit die locations 7 formed therein; two such integrated circuit die locations 7 are shown, but it should be understood that any number of such integrated circuit die locations 7 may be present. Each integrated circuit die location 7 has pads 12a and 12b formed on its front side.

Adhesive layers 30 are formed on the front side of each integrated circuit die location 7, as shown in FIG. 4, and then the back sides of integrated circuits 18 are attached to the adhesive layers 30, such that the back sides of integrated circuits 18 are attached to the front sides of the integrated circuit die locations 7. The integrated circuits 18 each have pads 19a-19d formed on their front sides.

A conformal deposit, for example, by spraying, is made of a layer of laser direct structuring (LDS) comparable resin 13′ on the combined structures of the integrated circuit die locations 7 and integrated circuit dice 18′, as shown in FIG. 5. In particular, the LDS compatible resin 13′ is sprayed on the exposed portions of the front sides of the integrated circuit die locations 7 and integrated circuit dice 18, and on the sides of the integrated circuits 18. The LDS compatible resin is infused or implanted with a laser-activated catalyst or particles that, when subjected to certain laser radiation, such as infrared (IR) laser radiation, become activated or exposed to form structured areas. These structured areas may then be turned into conductive areas via metallization.

For example, the LDS resin layer 13′ may have particles such as copper-chromium oxide spinel, copper sulfate, copper hydroxide phosphate, or cupric rhodanate embedded therein. The molding layer 13′ is then cured.

Next, as shown in FIG. 6, via cavities 71a-71b and 72a-72d through the LDS resin layer 13′ are formed by laser drilling, and a laser light is used to form a desired pattern of structured areas in the LDS resin layer 13′ by activating or exposing the catalyst in the walls of the via cavities 71a-71b and 72a-72d.

By structured area, it is meant an area in the LDS resin layer 13′ where the catalyst has been activated or exposed due to application of a laser light to the relevant portion of the LDS resin layer 13′. As will be explained below, structured areas can be metallized to form conductive areas. For example, laser activation can be applied to the walls of the via cavities 71a-71b and 72a-72d to structure those walls.

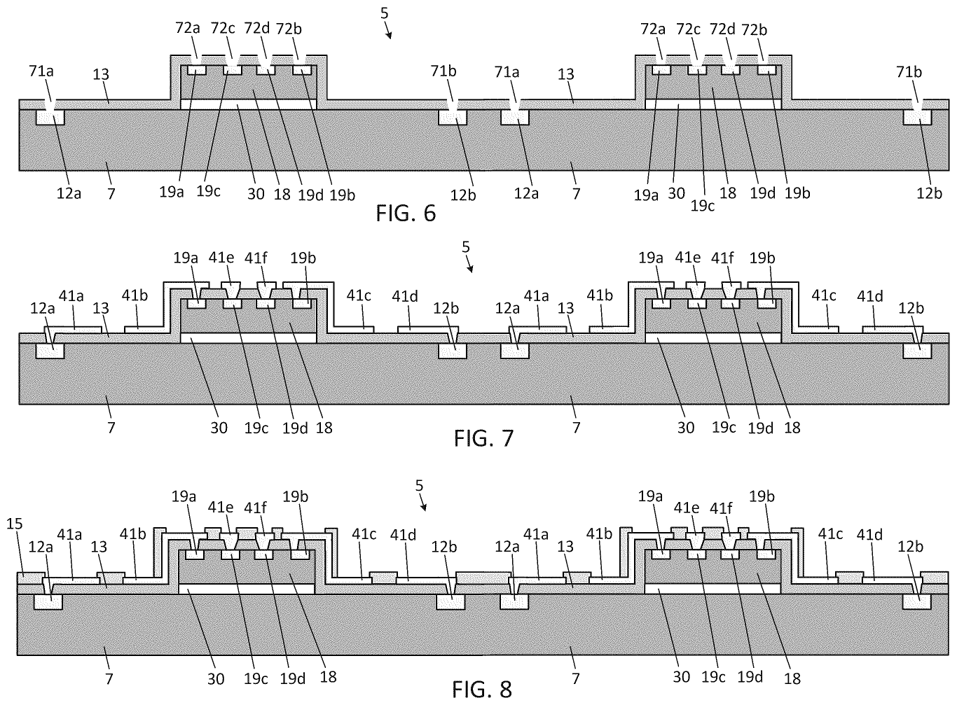

Thereafter, as shown in FIG. 7, a metallization process is performed to metallize the via cavities 71a-71b and 72a-72d and form traces connected to them and extending across the LDS resin layer 13′, thereby forming the interconnections 41a-41f. This metallization process may include a copper electroless deposition, where an appropriate wet chemical bath reacts with exposed chromium particles within the LDS resin layer 13′ to create a thin (e.g., 5 μm in thickness) copper pattern on the patterns of structured areas on the LDS resin layer 13′. This thin copper pattern can be thickened through electrodeposition to reach a desired thickness (e.g., 10 μm) that properly forms the interconnections 41a-41f.

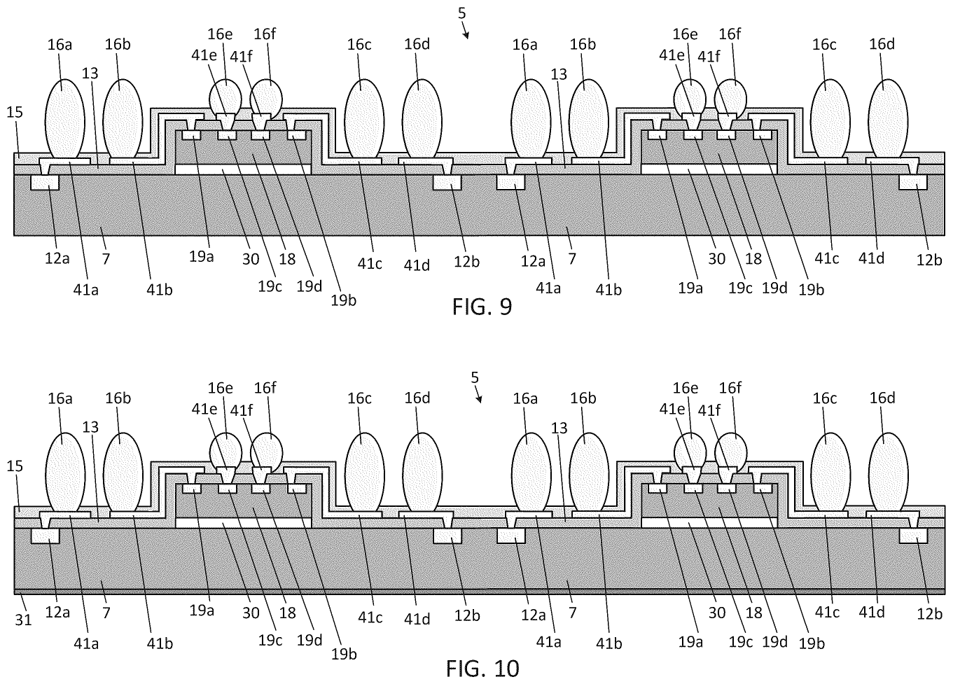

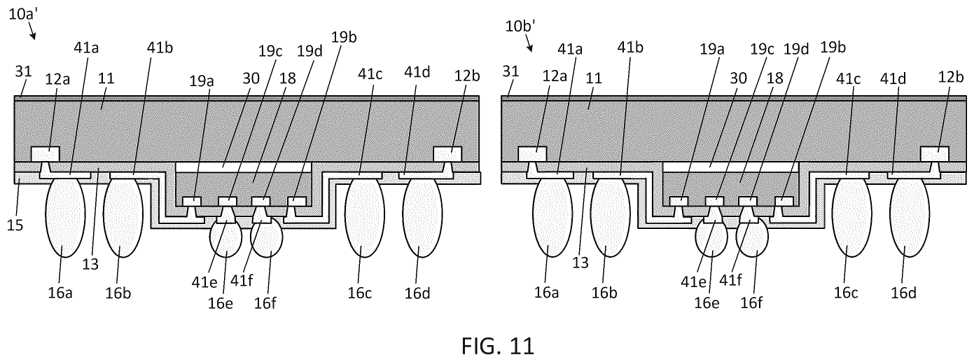

Next, as shown in FIG. 8, a solder resist layer 15 is formed over the LDS resin layer 13′ and interconnections 41a-41f. Then, solder balls 16a-16d are connected to the interconnections 41a-41d, and solder balls 16e-16f are connected to the interconnections 41e-41f, as shown in FIG. 9. A coating 31 is then applied to the back side of the integrated circuit die locations 7, as shown in FIG. 10, and then the wafer is singulated into integrated circuit dice 11 to form wafer-level packages 10a′ and 10b′, as shown in FIG. 11.

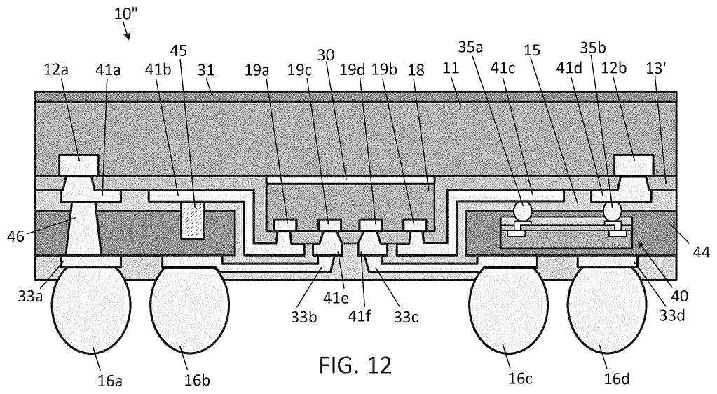

With initial reference to FIG. 12, a second wafer level package 10″ is now described. The second wafer level package 10″ is comprised of a first integrated circuit die 11 having pads 12a and 12b on its front side and a coating 31 on its back side, and a second integrated circuit die 18 having pads 19a-19b on its front side and having its back side facing the front side of the first integrated circuit die 11. An adhesive layer 30 attaches the back side of the second integrated circuit die 18 to the front side of the first integrated circuit die 11. Therefore, notice that the pads 12a and 12b of the first integrated circuit die 11 do not face the pads 19a-19b of the second integrated circuit die 18.

A resin layer 13′ is disposed on and across the front side of the front integrated circuit die 11, on and up the edge sides of the second integrated circuit die 18, and on and across the front side of the second integrated circuit die 18. A solder resist layer 15′ is disposed on and across the resin layer 13′.

A redistribution layer (RDL) is formed within and on the resin layer 13′ and covered by the solder resist layer 15′. The RDL includes interconnections 41a and 41d respectively connected to the pads 12a and 12b, and interconnections 41e and 41f respectively connected to the pads 19c and 19d. The RDL includes interconnections 41b and 41c extending from the pads 19a and 19b, across the portion of the resin layer 13′ on the front of the second die 18, down the portions of the resin layer 13′ on the edge sides of the second die 18, and across the portions of the resin layer 13′ on the front of the integrated circuit die 11.

Solder balls 35a and 35b are connected to the interconnections 41c and 41d, and to pads on a chip 40 having its front side facing the front side of the first integrated circuit die 11. A molding layer 44 encapsulates the chip 40, and extends along one side of the second integrated circuit die 18 and across a portion of the front face of the first integrated circuit die 15.

A passive component 45, such as a capacitor, is connected to the interconnection 41b. A via 46 is connected to the interconnection 41a. The molding layer 44 encapsulates the passive component 45, and extends along the other side of the second integrated circuit die 18 and across another portion of the front face of the first integrated circuit die 11.

Notice that the solder resist 14 also extends across the molding layer 44 and sandwiches the molding layer 44 on both of its sides. A pad 33a is in the solder resist 14 in the illustrated position opposite the interconnect 41a and is connected to the via 46, and a solder ball 16a is connected to the pad 33a. A pad and interconnect 33b extends in the solder resist 14 from the interconnect 41e to the illustrated position opposite the passive component 45 and interconnect 41b, and a solder ball 16b is connected to the pad 33b. A pad and interconnect 33c extends in the solder resist 14 from the interconnect 41f to the illustrated position opposite the chip 40 and interconnect 41c, and a solder ball 16c is connected to the pad 33c. A pad 33d is in the solder resist 14 opposite the interconnect 41d, and a solder ball 16d is connected to the pad 33d.

Of note here is that the interconnections 41a-41f are not formed by drilling and filling. The interconnections 41a-41f are formed by activating desired areas of the resin layer 13′ (and drilling appropriate areas prior to activation of the desired areas and the walls of the holes formed via drilling), which contains an activatable catalyst, and then plating the activated areas. Also of note is that the pads 33a, pads and interconnects 33b, pads and interconnects 33c, and pads 33d within the solder resist 15, as well as the vias 46, are formed by conventional techniques and not using LDS techniques.

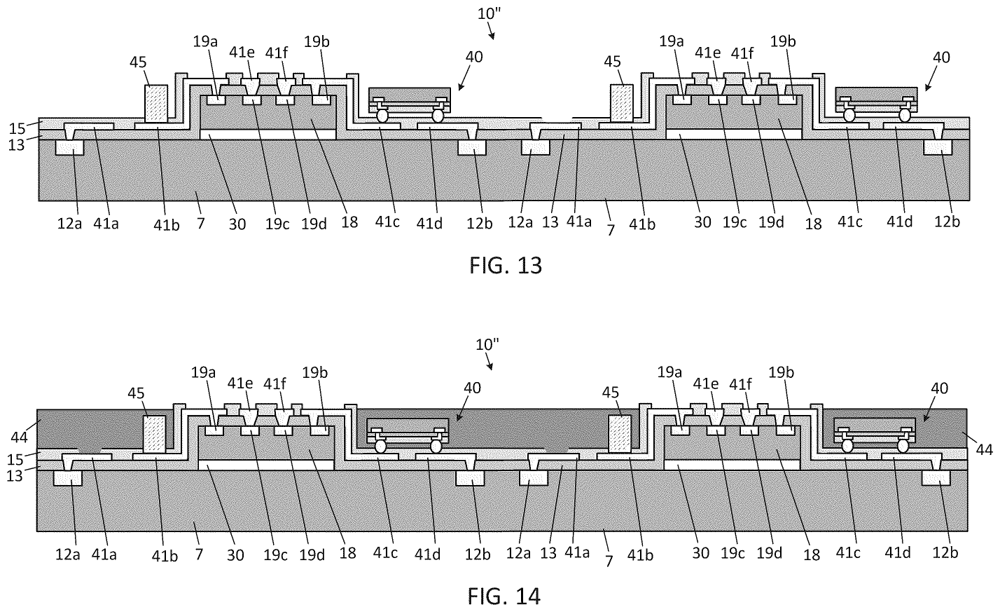

Formation begins of the second wafer level package 10″ begins the same as the first wafer level package 10′, as described above with reference to FIGS. 3-8. The remainder of the formation of the second wafer level package 10″ is now described with additional reference to drawing FIGS. 13-19. After forming of the solder resist layer 16 over the LDS resin layer 13′ and interconnections 41a-41f, passive components 45 are attached to the interconnections 41b, as shown in FIG. 13. Additionally, chips 40 are attached to interconnections 41c and 41d at this point.

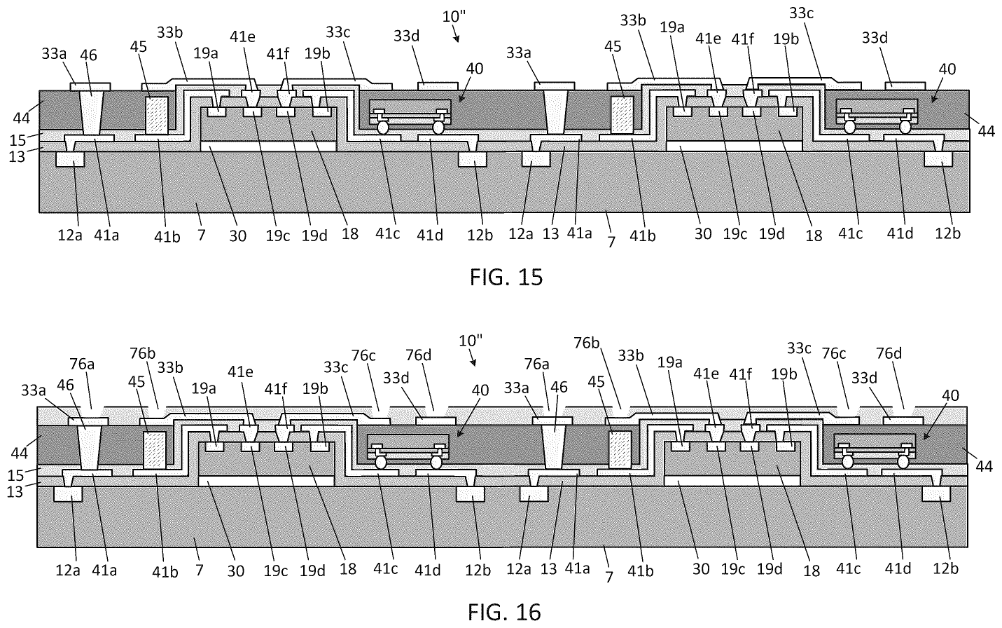

Next, as shown in FIG. 14, a molding layer 44 is deposited over the solder resist 15, passive components 45, and chips 40. Then, as shown in FIG. 15, vias 46 are formed in the molding layer 44 using conventional techniques, extending from a front face of the molding layer 44 to reach the interconnections 41a.

Pads 33a are formed in the solder resist 14 in the illustrated positions opposite the interconnects 41a and are connected to the vias 46, and solder balls 16a are connected to the pads 33a, using conventional techniques.

Pads and interconnects 33b are formed to extend in the solder resist 14 from the interconnects 41e to the illustrated positions opposite the passive components 45 and interconnects 41b, and solder balls 16b are connected to the pads 33b, using conventional techniques. Pads and interconnects 33c are formed to extend in the solder resist 14 from the interconnects 41f to the illustrated position opposite the chips 40 and interconnects 41c, and solder balls 16c are connected to the pads 33c, using conventional techniques. Pads 33d are formed in the solder resist 14 opposite the interconnects 41d, and solder balls 16d are connected to the pads 33d, also using conventional techniques.

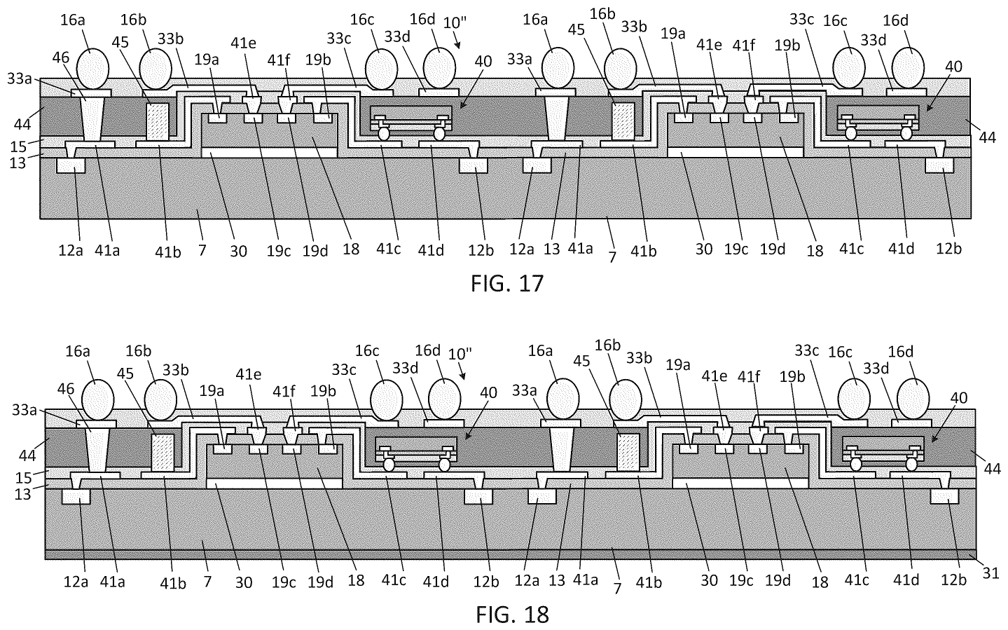

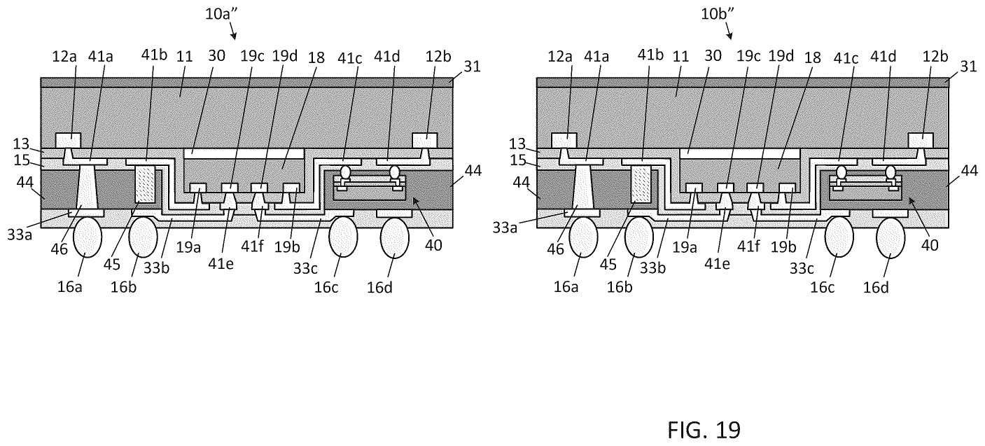

Then, as shown in FIG. 16, an additional portion of the solder resist 15 is formed over the molding layer 44, and holes 76a-76d are drilled in the molding layer 44. Thereafter, solder balls 16a-16d are connected to the pads and interconnects 33a-33d, as shown in FIG. 17, and a coating 31 is applied to the back side of the integrated circuit die locations 7, as shown in FIG. 18, and then the integrated circuits are singulated into integrated circuit die 10a″ and 10b″, as shown in FIG. 19.

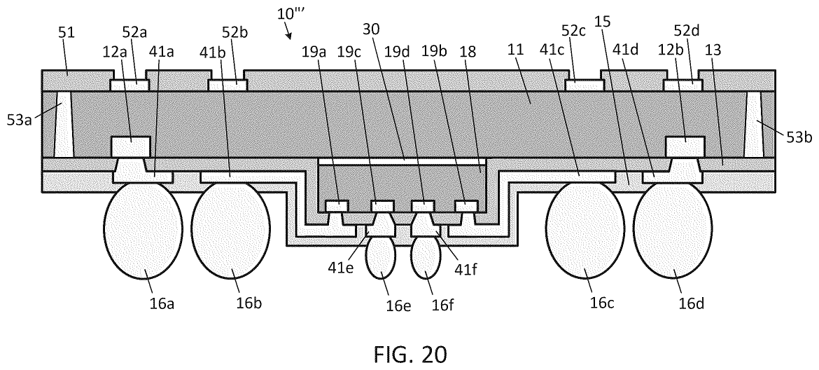

Understand that the embodiments given above are examples of the possibilities possible when using LDS techniques. Another example is shown in the package 10′″ of FIG. 20, which is the same as the package 10′ as in FIG. 2A, except here another solder resist layer 51 is deposited on the back side of the integrated circuit die locations 7, and pads 52a-52d are formed thereon. Connectors 53a and 53b extent through the integrated circuit die locations 7 to provide interconnection between components in the solder resist layers 51 and 13.

While the disclosure has been described with respect to a limited number of embodiments, those skilled in the art, having benefit of this disclosure, will appreciate that other embodiments can be envisioned that do not depart from the scope of the disclosure as disclosed herein. Accordingly, the scope of the disclosure shall be limited only by the attached claims.

1. A wafer-level package, comprising:
a first integrated circuit die including a front side with a plurality of pads;
a second integrated circuit die including a front side with a plurality of pads, wherein an adhesive layer affixes a back side of the second integrated circuit die to the front side of the first integrated circuit die;
a resin layer surrounding edge sides of the second integrated circuit die and the front side of the second integrated circuit die, and surrounding the front side of the first integrated circuit die, wherein the resin layer includes an activatable catalyst material;
a solder resist layer having a back surface in contact with a front surface of the resin layer; and
a redistribution layer comprising:
first activated and metallized portions of the resin layer adjacent the plurality of pads on the front side of the second integrated circuit die;
second activated and metallized portions of the resin layer adjacent the plurality of pads on the front side of the first integrated circuit die; and
third activated and metallized portions of the resin layer extending from given ones of the first activated and metallized portions of the resin layer, down the edge sides of the second integrated circuit die, and across portions of the resin layer on the front side of the first integrated circuit die, to thereby electrically connection given ones of the plurality of pads on the front side of the second integrated circuit die to locations on the resin layer on the front side of the first integrated circuit die.

2. The wafer-level package of claim 1, further comprising fourth activated and metallized portions of the resin layer electrically connecting certain ones of the first activated and metallized portions of the resin layer to certain ones of the second activated and metallized portions of the resin layer to thereby electrically connect certain pads on the front side of the second integrated circuit die to certain pads on the front side of the first integrated circuit die.

3. The wafer-level package of claim 1, further comprising:
a fourth activated and metallized portion of the resin layer on the front side of the first integrated circuit die;
a fifth activated and metallized portion of the resin layer electrically connecting one of the first activated and metallized portions to the fourth activated and metallized portion of the resin layer; and
a passive component electrically connected to the fourth activated and metallized portion of the resin layer.

4. The wafer-level package of claim 3, further comprising a molding layer encapsulating the passive component.

5. The wafer-level package of claim 4, further comprising:
a molding layer encapsulating a portion of the first integrated circuit die and one of the second activated and metallized portions of the resin layer;
a pad formed on the molding layer; and
a via extending from the pad formed on the molding layer, through the molding layer, to contact the one of the second activated and metallized portions of the resin layer to thereby electrically connect the pad formed on the molding layer to the one of the second activated and metallized portions of the resin layer.

6. The wafer-level package of claim 1, further comprising a chip connected to one of the third activated and metallized portions of the resin layer on the front side of the first integrated circuit die.

7. The wafer-level package of claim 6, further comprising a molding layer encapsulating the chip.

8. The wafer-level package of claim 7, wherein the molding layer encapsulating the chip extends along one side of the second integrated circuit die and across a portion of the front side of the first integrated circuit die.

9. The wafer-level package of claim 1, wherein the activatable catalyst material comprises at least one of copper-chromium oxide spinel, copper sulfate, copper hydroxide phosphate, or cupric rhodanate.

10. The wafer-level package of claim 1, wherein the solder resist layer extends across the resin layer on the front side of the first integrated circuit die and on the front side of the second integrated circuit die.

11. The wafer-level package of claim 1, further comprising a coating on a back side of the first integrated circuit die.

12. The wafer-level package of claim 1, further comprising a second solder resist layer disposed on a back side of the first integrated circuit die and pads formed thereon.

13. The wafer-level package of claim 12, further comprising connectors extending through the first integrated circuit die to provide electrical interconnection between the second solder resist layer and the resin layer.

14. A wafer-level package, comprising:
a first integrated circuit die including a front side with a plurality of pads;
a second integrated circuit die including a front side with a plurality of pads, wherein a back side of the second integrated circuit die faces the front side of the first integrated circuit die and is attached thereto by an adhesive layer;
a resin layer disposed on and across the front side of the first integrated circuit die, along edge sides of the second integrated circuit die, and across the front side of the second integrated circuit die, the resin layer containing an activatable catalyst material; and
a redistribution layer formed by activated and metallized portions of the resin layer, the redistribution layer including interconnections extending from pads on the front side of the second integrated circuit die, along the edge sides of the second integrated circuit die, and across the resin layer on the front side of the first integrated circuit die to electrically connect the first and second integrated circuit dies.

15. The wafer-level package of claim 14, wherein the activated and metallized portions of the resin layer are defined by selective laser activation of the catalyst material within the resin layer.

16. The wafer-level package of claim 14, wherein the metallized portions of the resin layer are formed by plating on the activated portions of the resin layer.

17. The wafer-level package of claim 14, further comprising a solder resist layer disposed over the resin layer and covering the redistribution layer.

18. The wafer-level package of claim 14, wherein the resin layer comprises a laser direct structuring compatible material having embedded catalyst particles that become activatable when exposed to laser radiation.

19. The wafer-level package of claim 14, wherein the redistribution layer provides electrical connection between at least one pad on the front side of the second integrated circuit die and at least one pad on the front side of the first integrated circuit die.

20. The wafer-level package of claim 14, further comprising solder balls connected to metallized portions of the resin layer on the front side of the first integrated circuit die.
